(19) United States
(12) Patent Application Publication
(10) Pub. No.: US 2024/0222154 A1
(43) Pub. Date: Jul. 4, 2024

(54) APPARATUS FOR PROCESSING SUBSTRATE

(71) Applicant: SEMES CO., LTD., Chungcheongnam-do (KR)

(72) Inventors: Won Sik SON, Gyeonggi-do (KR); Ho Jong HWANG, Gyeonggi-do (KR); Hyun Goo PARK, Gyeonggi-do (KR)

(21) Appl. No.: 18/507,008

(22) Filed: Nov. 10, 2023

(30) Foreign Application Priority Data
Dec. 29, 2022 (KR) 10-2022-0188700

(51) Int. Cl. H01L 21/67; B08B 3/10; B08B 5/02; B08B 7/00

(52) U.S. Cl. CPC H01L 21/67028; B08B 3/10; B08B 5/02; B08B 7/0021; B08B 2203/007

(57) ABSTRACT

A substrate processing apparatus using a supercritical fluid that can remove floating particles is provided. The substrate processing apparatus comprises a vessel including a processing space for processing a substrate, and a first vessel and a second vessel configured to be combined to be open and closed, wherein the first vessel and the second vessel seal the processing space in a closed position, and the first vessel and the second vessel open the processing space in an open position; a clamping unit configured to clamp the first vessel and the second vessel in the closed position; and an intake unit configured to intake a particle by including an intake member positioned to correspond to an open space between the first vessel and the second vessel in the open position.

This application claims the benefit of Korean Patent Application No. 10-2022-0188700, filed on Dec. 29, 2022, in the Korean Intellectual Property Office, the disclosure of which is incorporated herein by reference in its entirety.

### BACKGROUND

### 1. Field

The present invention relates to a substrate processing apparatus, and to a substrate processing apparatus using a supercritical fluid.

2. Description of the Related Art

As semiconductor devices become more highly integrated, individual circuit patterns are becoming more refined in order to implement more semiconductor devices in the same area. Supercritical fluids are used in various processes (e.g., drying, deposition) of miniaturized semiconductor devices. This is because a supercritical fluid is a substance placed at a temperature and pressure above a critical point, and has the diffusivity of a gas and the solubility of a liquid. Taking the drying process as an example, the supercritical fluid easily penetrates into the pattern on the substrate, and the supercritical fluid easily dissolves the remaining rinse solution (e.g., organic solvent). Accordingly, the rinse solution remaining between the patterns formed on the substrate is easily removed.

### SUMMARY

Meanwhile, a substrate processing apparatus using a supercritical fluid comprises a heating unit for heating the fluid to a high temperature in order to generate and maintain the supercritical fluid. The ambient temperature of the heating unit is higher than that of other units, and if the airflow around the heating unit becomes stagnant, particles may float around the heating unit.

The problem to be solved by the present invention is to provide a substrate processing apparatus using a supercritical fluid that can remove floating particles.

The objects of the present invention are not limited to the objects mentioned above. and other objects not mentioned will be clearly understood by those skilled in the art from the description below.

One aspect of the substrate processing apparatus of the present invention for achieving the above object comprises a vessel including a processing space for processing a substrate, and a first vessel and a second vessel configured to be combined to be opened and closed, wherein the first vessel and the second vessel seal the processing space in a closed position, and the first vessel and the second vessel open the processing space in an open position; a clamping portion configured to clamp the first vessel and the second vessel in the closed position; and an intake unit configured to intake a particle by including an intake member positioned to correspond to an open space between the first vessel and the second vessel in the open position.

Another aspect of the substrate processing apparatus of the present invention comprises a liquid processing chamber configured to supply a processing liquid to a substrate; a drying chamber configured to remove processing liquid remaining on the substrate processed in the liquid processing chamber; and a transfer chamber for moving the substrate from the liquid processing chamber to the drying chamber, wherein the drying chamber comprises, a vessel including a processing space for processing a substrate, and a first vessel and a second vessel configured to be combined to be open and closed, wherein the first vessel and the second vessel seal the processing space in a closed position, and the first vessel and the second vessel open the processing space in an open position, a clamping unit configured to clamp the first vessel and the second vessel in the closed position, an intake member configured to intake a particle by including an intake member positioned to correspond to an open space between the first vessel and the second vessel in the open position.

Still another aspect of the substrate processing apparatus of the present invention comprises a vessel including a processing space for processing a substrate using a fluid, and a first vessel and a second vessel configured to be combined to be open and closed, wherein the first vessel and the second vessel seal the processing space in a closed position. and the first vessel and the second vessel open the processing space in an open position; a heating unit for increasing a temperature of a fluid supplied to the vessel; a clamping unit configured to clamp the first vessel and the second vessel in the closed position; an intake unit configured to intake a particle by including an intake member positioned to correspond to an open space between the first vessel and the second vessel in the open position; a cleaning unit positioned to correspond to the open space between the first vessel and the second vessel in the open position, and for supplying an inert gas to the open space to perform a blow operation before the intake unit performs an intake operation; and a cover unit installed in the clamping unit and disposed between the vessel and the heating unit, and for blocking airflow from a space where the heating unit is installed to a space where the vessel is installed, wherein the clamping unit comprises, a first clamp for clamping one side of the vessel in the closed position and comprising a first groove; a second clamp for clamping the other side of the vessel in the closed position and comprising a second groove, wherein the intake member comprises, a first intake member installed in the first clamp at a position corresponding to the first groove, a second intake member installed in the second clamp at a position corresponding to the second groove, wherein the cover unit comprises, a first cover installed on the first clamp and disposed outside the first intake member, and a second cover installed on the second clamp and disposed outside the second intake member, wherein an area where the first cover and the second cover overlap when the clamping unit is in the locked position is larger than an area where the first cover and the second cover overlap when the clamping unit is in the unlocked position.

Specific details of other embodiments are included in the detailed description and drawings.

### BRIEF DESCRIPTION OF THE DRAWINGS

These and/or other aspects will become apparent and more readily appreciated from the following description of the embodiments, taken in conjunction with the accompanying drawings in which:

FIG. 1 is a diagram for explaining a substrate processing apparatus according to some embodiments of the present invention;

FIGS. 2 and 3 are diagrams for explaining the operation of the clamping unit and vessel shown in FIG. 1;

FIG. 4 is a cross-sectional view taken along line A-A of FIG. 1, and is a view for explaining the intake unit;

FIG. 5 is a side view of FIG. 2 viewed from direction B, and is a view for explaining the intake unit;

FIG. 6 is a diagram for explaining the operation of the intake unit shown in FIG. 5;

FIGS. 7 and 8 are diagrams for explaining the effect of the intake unit;

FIG. 9 is a diagram for explaining a substrate processing apparatus according to some embodiments of the present invention;

FIGS. 10 and 11 are diagrams for explaining a substrate processing apparatus according to some embodiments of the present invention;

FIG. 12 is a diagram for explaining the arrangement of the cover unit of FIG. 10;

FIG. 13 is a diagram for explaining the operation of the cover unit of FIG. 10;

FIG. 14 is a diagram for explaining a substrate processing apparatus according to some embodiments of the present invention;

FIG. 15 is a diagram for explaining a substrate processing apparatus according to some embodiments of the present invention;

FIGS. 16 and 17 are diagrams for explaining a substrate processing apparatus according to some embodiments of the present invention; and

FIG. 18 is a conceptual diagram illustrating a substrate processing apparatus according to some embodiments of the present invention.

### DETAILED DESCRIPTION

Hereinafter, preferred embodiments of the present invention will be described in detail with reference to the attached drawings. The advantages and features of the present invention and methods for achieving them will become clear by referring to the embodiments described in detail below along with the accompanying drawings. However, the present invention is not limited to the embodiments disclosed below and may be implemented in various different forms. The present embodiments are merely intended to ensure that the disclosure of the present invention is complete and to full inform those skilled in the technical field to which the present invention pertains on the scope of the invention, and the present invention is only defined by the scope of the claims. Like reference numerals refer to like elements throughout the specification.

Spatially relative terms such as “below,” “beneath,” “lower,” “above,” “upper,” etc. can be used to easily describe the correlation between one elements or components and other elements or components. Spatially relative terms should be understood as terms that include different directions of the element during use or operation in addition to the direction shown in the drawings. For example, if an element shown in the drawings is turned over, an element described as “below” or “beneath” another element may be placed “above” the other element. Accordingly, the illustrative term “below” may include both downward and upward directions. Elements can also be oriented in other directions, so spatially relative terms can be interpreted according to orientation.

Although first, second, etc. are used to describe various components, elements and/or sections, it is understood that these components, elements and/or sections are not limited by these terms. These terms are merely used to distinguish one component, element, or section from other components, elements, or sections. Therefore, the first component, first element, or first section mentioned below may also be a second component, second element, or second section within the technical spirit of the present invention.

Hereinafter, embodiments of the present invention will be described in detail with reference to the accompanying drawings. In the description with reference to the accompanying drawings, identical or corresponding components will be assigned the same reference numbers regardless of the reference numerals, and the redundant explanation for this will be omitted.

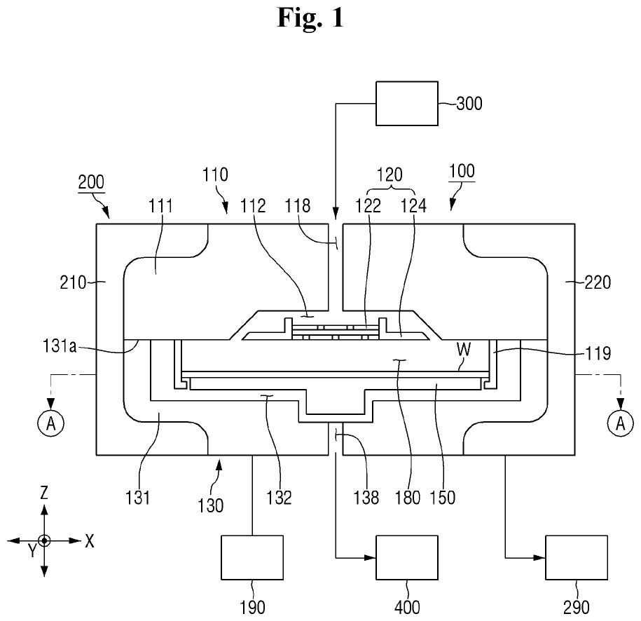

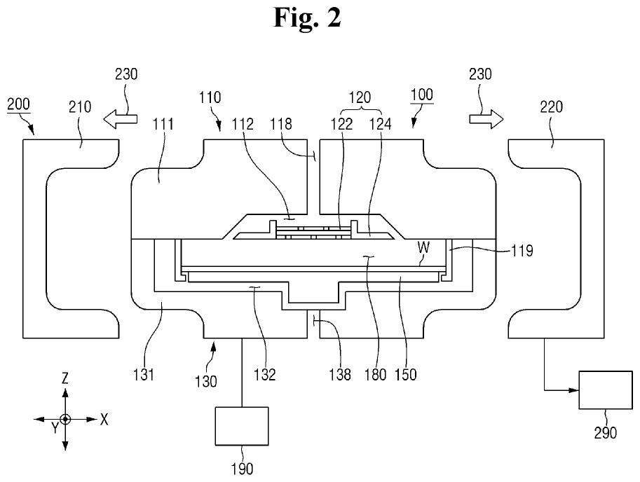

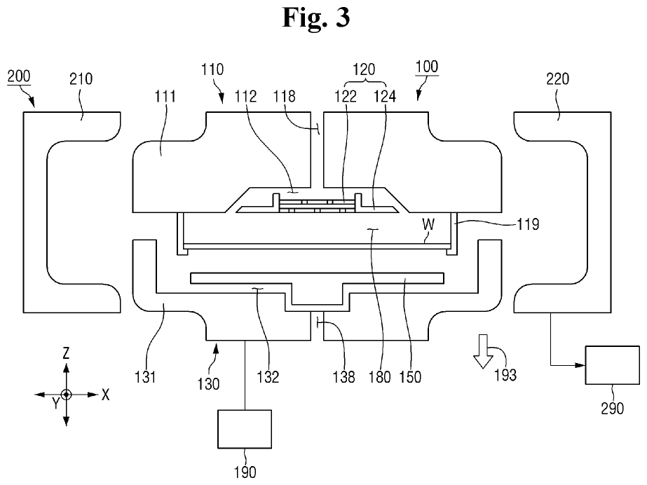

FIG. 1 is a diagram for explaining a substrate processing apparatus according to some embodiments of the present invention. FIGS. 2 and 3 are diagrams for explaining the operation of the clamping unit and vessel shown in FIG. 1.

A substrate processing device according to some embodiments of the present invention can be applied to a process (e.g., drying process) using a supercritical fluid. A supercritical fluid is a substance placed at a temperature and pressure above a critical point, and has the diffusivity of a gas and the solubility of a liquid. Carbon dioxide (CO₂), water (H₂O), methane (CH₄), ethane (C₂H₆), propane (C₃H₈), ethylene (C₂H₄), propylene (C₃H₆), methanol (CH₃OH), ethanol (C₂H₅OH), and acetone (C₃H₆O), etc. may be used as a supercritical fluid, but are not limited thereto. Carbon dioxide is explained as an example of a supercritical fluid below.

Referring to FIG. 1, a substrate processing apparatus according to some embodiments of the present invention comprises a reactor 100, a clamping unit 200, a process fluid supply unit 300, an exhaust unit 400, a driving unit 190, 290, etc. The operations of the reactor 100, clamping unit 200, process fluid supply unit 300, exhaust unit 400, and driving units 190 and 290 may be controlled by a controller (not shown).

The reactor 100 is a space where a process for supercritical fluid progresses. This reactor 100 comprises an upper vessel 110, a support 119, a baffle plate 120, a lower vessel 130, a support plate 150, etc.

The vessels 110 and 130 provide a processing space 180 for processing the substrate W. The vessels 110 and 130 include an upper vessel 110 and a lower vessel 130, which are combined to be opened and closed. Specifically, the first driving unit 190 moves at least one of the upper vessel 110 and the lower vessel 130 to determine the relative position. By the first driving unit 190, the upper vessel 110 and the lower vessel 130 can move between an open position (see FIG. 3) that opens the processing space 180 and a closed position (see FIG. 1) that seals the processing space.

The upper vessel 110 includes a first body 111, a supply port 118, and a first accommodation space 112.

The first body 111 serves as the body of the upper vessel 110, and a supply port 118 and a first accommodation space 112 are formed therein.

The supply port 118 may be installed to penetrate the first body 111. The supply port 118 receives the process fluid (i.e., supercritical fluid) from the process fluid supply unit 300 and delivers it to the first accommodation space 112.

The first accommodation space 112 may be formed on the lower surface (or bottom surface) of the first body 111. As shown, the first accommodation space 112 may be recessed inward from the lower surface of the first body 111. The depth of the first accommodation space 112 may be, for example, 10 mm or more. As shown, the side surface of the first accommodation space 112 may be inclined. That is, the side and top surfaces of the first accommodation space 112 may have an angle less than 90 degrees (for example, 10 to 70 degrees).

The baffle plate 120 is installed in the first accommodation space 112. The baffle plate 120 diffuses the process fluid supplied by the supply port 118 and supplies it to the processing space 180.

This baffle plate 120 includes a base 124 and a perforated plate 122. The perforated plate 122 is fixed by the base 124 and may be, for example, stacked in two or more layers. The perforation position of the perforated plate 122 installed below may be different from the perforated position of the perforated plate 122 installed immediately above. That is, when viewed in the vertical direction, the perforated positions of the perforated plate 122 installed below are not aligned with the perforated positions of the perforated plate 122 installed immediately above. By not arranging the perforation positions in a line, the process fluid is sufficiently mixed and supplied to the substrate W through the first accommodation space 112 and the baffle plate 120.

The support 119 is installed on the lower surface of the upper vessel 110. When the vessels 110 and 130 are in the open position (the upper vessel 110 and the lower vessel 130 are spaced apart), the support 119 is configured to support the substrate W.

The lower vessel 130 includes a second body 131, an exhaust port 138, a second accommodation space 132, etc.

The second body 131 serves as the body of the lower vessel 130, and the exhaust port 138 and the second accommodation space 132 are formed therein.

The exhaust port 138 may be installed to penetrate the second body 131. The exhaust port 138 exhausts the process fluid from the processing space 180 to the outside. The exhaust operation can be controlled by the operation of the exhaust unit 400 connected to the exhaust port 138.

The second accommodation space 132 may be installed on the upper surface of the second body 131. As shown, the second accommodation space 132 may be recessed inward from the upper surface of the second body 131. The second accommodation space 132 is defined by a side wall protruding toward the upper vessel 110. The top surface 131a of the side wall may contact the first body 111 of the upper vessel 110.

The support plate 150 is installed in the lower vessel 130 to face the baffle plate 120, and specifically, the support plate 150 is installed in the second accommodation space 132. When the vessels 110, 130 move from the open position to the closed position (with the upper vessel 110 and lower vessel 130 in contact), the substrate W may be transmitted from the support 119 to the support plate 150 and supported by the support plate 150, but is not limited thereto.

The clamping unit 200 clamps the vessels 110 and 130 in the closed position. The clamping unit 200 may be composed of, for example, two clamps, but is not limited thereto. The clamping unit 200 may comprise a first clamp 210 that clamps one side (i.e., one side based on the first direction (X)) of the vessels 110 and 130 in the closed position, and a second clamp 220 that clamps the other side (that is, the other side based on the first direction (X)) of the vessels 110, 130 in the closed position.

The clamping unit 200 can be moved between the locked position and the unlocked position by the second driving unit 290. The locked position refers to the position of the clamping unit 200 that clamps the vessels 110 and 130 (see FIG. 1), and the unlocked position refers to the position of the clamping unit 200 that does not clamp the vessels 110 and 130 (see FIGS. 2 and 3).

Additionally, the upper edge of the upper vessel 110 may have a curved shape, and the lower edge of the lower vessel 130 may have a curved shape. The inner surface of the first clamp 210 and the inner surface of the second clamp 220 may have complementary shapes so as to be combined with the curved shapes of the upper vessel 110 and the lower vessel 130.

Hereinafter, the operation of the clamping unit 200 and the vessels 110 and 130 will be described using FIGS. 1 to 3. First, the operation of removing the substrate W from the vessels 110 and 130 will be described.

As shown in FIG. 1, the vessels 110 and 130, in which the supercritical process is performed, are in the closed position, and the clamping unit 200 is in the locked position. That is, the first vessel 110 and the second vessel 130 contact and combine with each other to seal the processing space 180, and the first clamp 210 clamps on one side of the first vessel 110 and the second vessel 130, and the second clamp 220 clamps on the other side of the first vessel 110 and the second vessel 130.

With the substrate W supported by the support plate 150, the process fluid supply unit 300 supplies the process fluid (i.e., supercritical fluid) into the processing space 180. Within the processing space 180, the processing liquid (e.g., rinse solution) remaining on the substrate W may be removed by the process fluid.

When the supercritical process is completed, as shown in FIG. 2, the clamping unit 200 is moved from the locked position to the unlocked position by the second driving unit 290 (see reference numeral 230). That is, the first clamp 210 is spaced apart from one side of the vessels 110 and 130, and the second clamp 220 is spaced apart from the other side of the vessels 110 and 130.

As shown in FIG. 3, the vessels 110 and 130 are moved from the closed position to the open position by the first driving unit 190 (see reference numeral 193). In FIG. 3, for example, the upper vessel 110 is fixed and the relative position is determined by moving the lower vessel 130 in the third direction (Z). As the lower vessel 130 moves in the third direction (Z), the processing space 180 is opened. Accordingly, a spaced apart space (i.e., an open space) is formed between the upper vessel 110 and the lower vessel 130.

As the lower vessel 130 moves in the third direction Z, the substrate W is moved from the support plate 150 to the support 119. Subsequently, the substrate W is taken out of the vessels 110 and 130 by a transfer robot.

Next, the operation of inserting the substrate W into the vessels 110 and 130 will be described. As shown in FIG. 3, the vessels 110 and 130 are in the open position, and the clamping unit 200 is also in the unlocked position. The transfer robot moves the substrate W to the support 119. The vessels 110, 130 then move from the open position to the closed position. As shown in FIG. 1, the clamping unit 200 moves from the unlocked position to the locked position. The substrate W moves from the support 119 to the support plate 150.

Meanwhile, when the vessels 110 and 130 move from the closed position to the open position, particles around the vessels 110 and 130 may penetrate into the vessels 110 and 130. A substrate processing apparatus according to some embodiments of the present invention includes an intake unit for removing particles. The structure and effects of the intake unit will be described in detail below.

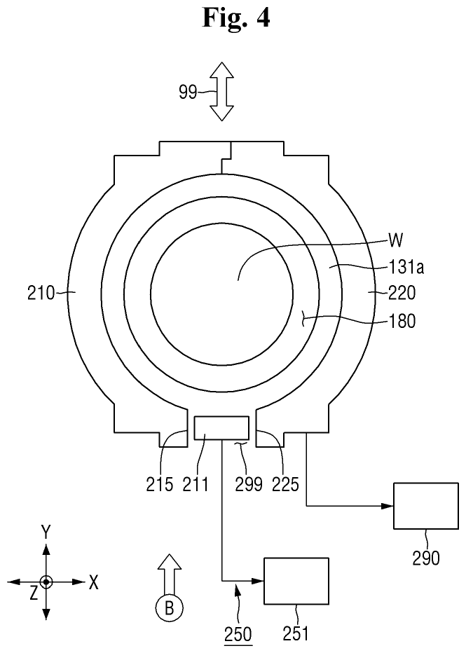

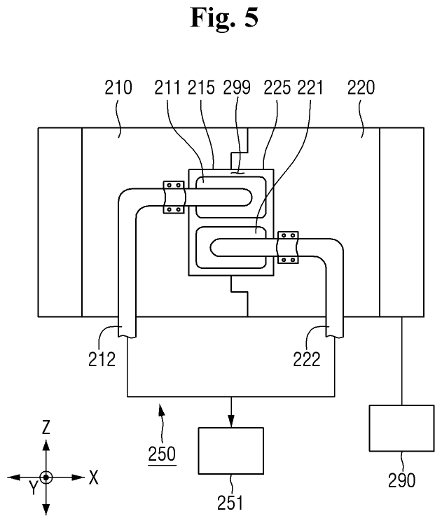

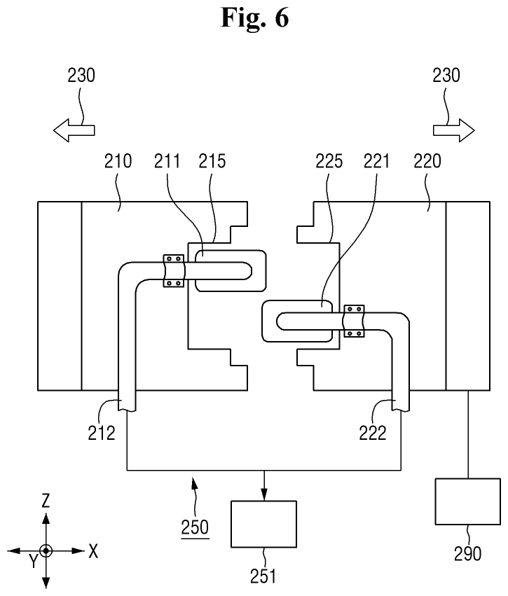

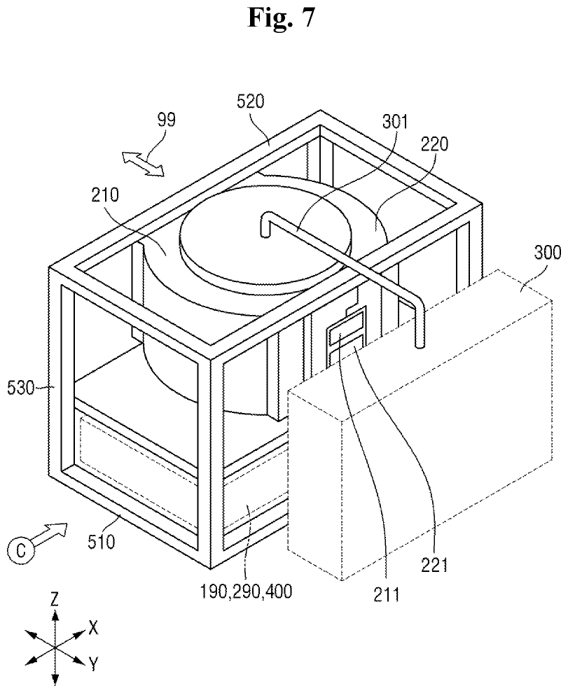

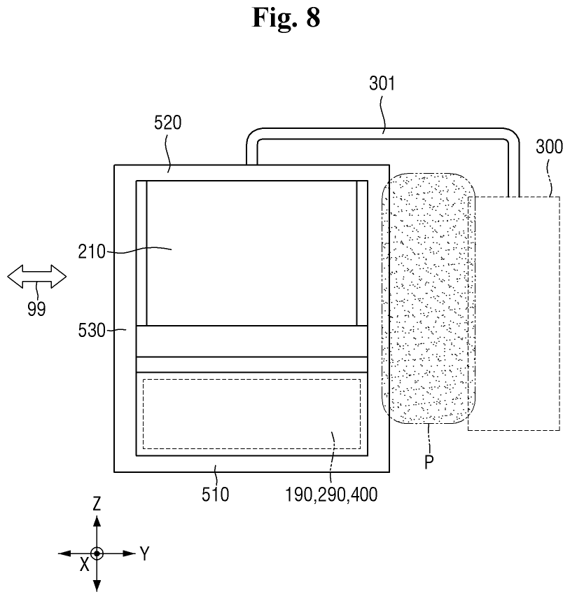

FIG. 4 is a cross-sectional view taken along line A-A of FIG. 1, and is a view for explaining the intake unit. FIG. 5 is a side view of FIG. 2 viewed from direction B, and is a view for explaining the intake unit. FIG. 6 is a diagram for explaining the operation of the intake unit shown in FIG. 5. FIGS. 7 and 8 are diagrams for explaining the effect of the intake unit.

First, referring to FIG. 7, a substrate processing apparatus according to some embodiments of the present invention comprises frames 510, 520, and 530 having an accommodation space therein. As shown, the frames 510, 520, and 530 include a lower frame 510, an upper frame 520, and a support frame 530. The support frame 530 is installed between the lower frame 510 and the upper frame 520.

As shown, a vessel (see 110 and 130 in FIG. 1) and a clamping unit (see 200 in FIG. 1) are disposed in the upper space of the accommodation space defined by the frames 510, 520, and 530.

In the lower space of the accommodation space, a first driving unit 190 for moving the vessels 110 and 130 to the open and closed positions, and a second driving unit 290 for moving the clamping unit 200 to the locked and unlocked positions are disposed.

Additionally, an exhaust unit 400 is disposed to exhaust the process fluid to the outside. At least one of the first driving unit 190, the second driving unit 290, and the exhaust unit 400 may be disposed in the lower space.

Additionally, the process fluid supply unit 300 generates a process fluid (i.e., supercritical fluid) and supplies it into the vessels 110 and 130 through the pipe 301. In order to generate and maintain a supercritical fluid, the process fluid supply unit 300 should increase the temperature of the fluid by heating it to a preset temperature or higher (for example, 200° C. or higher). Accordingly, the process fluid supply unit 300 includes a heating unit for heating the fluid.

Alternatively, the process fluid supply unit 300 may include a heating unit for maintaining the generated supercritical fluid.

Additionally, the exhaust unit 400 also includes a heating unit to maintain the temperature of the discharged process fluid.

The substrate W is introduced into the processing space 180 from the first side (e.g., from one side based on the second direction (Y)) of the vessels 110 and 130 (see reference numeral 99). On the other hand, the process fluid supply unit 300 (i.e., the heating unit) may be disposed on the second side of the vessels 110 and 130 (e.g., on the other side based on the second direction (Y)).

The heating units of the process fluid supply unit 300 and the exhaust unit 400 generate heat during operation. Additionally, the driving units 190 and 290 may generate heat and particles during operation.

As shown in FIG. 8, in the space (see reference numeral P) between the vessels 110, 130/clamping unit 200, driving units 190, 290, exhaust unit 400, and process fluid supply unit 300, airflow may become stagnant due to the influence of the generated heat. Within this area of stagnant airflow, the generated particles float. In a state in which particles are floating, when the vessels 110 and 130 are opened (i.e., moved to the open position), due to the pressure difference, the floating particles may penetrate into the processing space 180 inside the vessels 110 and 130 and be absorbed to the substrate (W). As a result, process defects may occur.

This airflow stagnation area is not only generated by the driving units 190 and 290, the exhaust unit 400, and the process fluid supply unit 300, but can also be generated by other influences. Alternatively, it may be generated only by the driving units 190 and 290, only by the exhaust unit 400, or only by the process fluid supply unit 300.

Meanwhile, the substrate processing apparatus according to some embodiments of the present invention includes an intake unit 250 for removing generated particles to prevent particles from penetrating into the processing space 180.

Specifically, referring to FIGS. 4 and 5, when viewed from the second direction (Y), a first groove 215 is formed in the first clamp 210, and a second groove 215 is formed in the second clamp 220. The vessels 110 and 130 can be identified through the first groove 215 and the second groove 225. The first groove 215 and the second groove 225 are installed at a similar height (that is, a height when viewed in the third direction (Z)). Accordingly, when the first clamp 210 and the second clamp 220 are in the locked position, the first groove 215 and the second groove 225 can be merged to form the window 299. At least a portion of the vessels 110 and 130 in the closed position are exposed through the window 299.

The intake unit 250 may include intake members 211 and 221, pipes 212 and 222, and a negative pressure providing unit 251.

Exemplarily, the first intake member 211 is connected to the first pipe 212, and the first pipe 212 is connected to the negative pressure providing unit 251. The second intake member 221 is connected to the second pipe 222, and the second pipe 222 is connected to the negative pressure providing unit 251. The first pipe 212 is installed in the first clamp 210, and the second pipe 222 is installed in the second clamp 220. The negative pressure provided from the negative pressure providing unit 251 is transmitted to the first intake member 211 through the first pipe 212 and transmitted to the second intake member 221 through the second pipe 222.

The intake members 211 and 221 are formed at positions corresponding to the windows 299. For example, the first intake member 211 may be formed to extend in the first direction (X) and span the first groove 215 and the second groove 225. The second intake member 221 may be formed to extend in the first direction (X) and span the first groove 215 and the second groove 225.

In particular, the position where the intake members 211 and 221 are installed is a position corresponding to the open space of the vessels 110 and 130 in the open position. As described above, the open space of the vessels 110 and 130 refers to the space between the upper vessel 110 and the lower vessel 130, which is generated when the upper vessel 110 and the lower vessel 130 are spaced apart from each other. That is, the intake members 211 and 221 are disposed between the open space and the heating unit of the process fluid supply unit 300.

By performing the intake operation at a position corresponding to the open space of the intake members 211 and 221, particles can be prevented from penetrating into the processing space 180 inside the vessels 110 and 130. For example, the intake operation may be performed together with the vessels 110 and 130 being opened, or may be performed before the vessels 110 and 130 are opened. Alternatively, the intake operation may be performed in the entire section excluding sections where the intake operation is unnecessary.

Additionally, in FIG. 4, the intake members 211 and 221 are shown as being disposed within the window 299, but the present invention is not limited thereto. For example, the intake members 211 and 221 are positioned to face the window 299, but do not need to be inside the window 299.

Also, referring to FIG. 6, since the intake members 211 and 221 and the pipes 212 and 222 are installed in the clamps 210 and 220, as clamps 210 and 220 move from the locked position to the unlocked position (see reference numeral 230), the intake members 211 and 221 and pipes 212 and 222 also move together with the clamps 210 and 220. That is, there is no need to provide a separate driving unit to move the intake members 211 and 221.

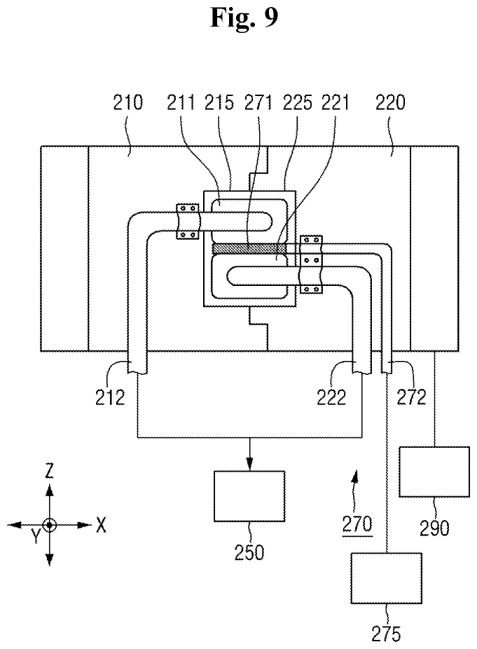

FIG. 9 is a diagram for explaining a substrate processing apparatus according to some embodiments of the present invention. For convenience of explanation, differences from those described using FIGS. 1 to 8 will be mainly explained.

Referring to FIG. 9, the substrate processing apparatus according to some embodiments of the present invention further comprises a cleaning unit 270.

The cleaning unit 270 includes a blow member 271, a third pipe 272, and an inert gas providing unit 275.

Exemplarily, the blow member 271 is connected to the third pipe 272, and the third pipe 272 is connected to the inert gas providing unit 275. The third pipe 272 may be installed in at least one of the first clamp 210 and the second clamp 220, and is shown as installed in the second clamp 220 in the drawing. The inert gas provided from the inert gas providing unit 275 is delivered to the blow member 271 through the third pipe 272. Inert gases may include, for example, nitrogen (N2), helium (He), argon (Ar), etc., but are not limited thereto.

The blow member 271 is formed at a position corresponding to the window 299. For example, the blow member 271 may be formed to extend in the first direction (X) and span the first groove 215 and the second groove 225.

In particular, the position where the blow member 271 is installed is a position corresponding to the open space of the vessels 110 and 130 in the open position. The blow member 271 is disposed between the open space and the heating unit of the process fluid supply unit 300.

In the drawing, the blow member 271 is shown as being disposed between the first intake member 211 and the second intake member 221, but the blow member 271 is not limited thereto. For example, in the third direction (Z), the first intake member 211, the second intake member 221, and the blow member 271 may be arranged in order.

Before the intake operation is performed by the intake members 211 and 221, the blow member 271 may perform a blow operation by supplying an inert gas to the open space. By doing this, the efficiency of the intake operation of the intake members 211 and 221 can be increased.

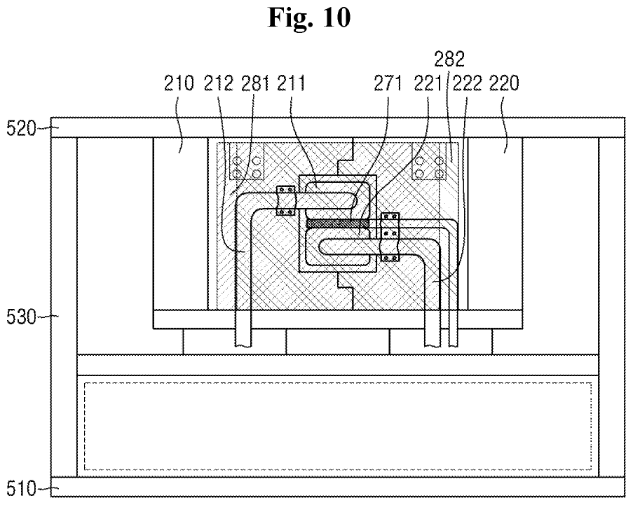

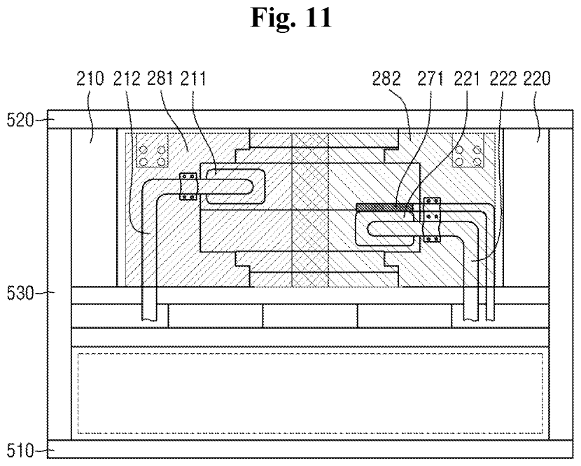

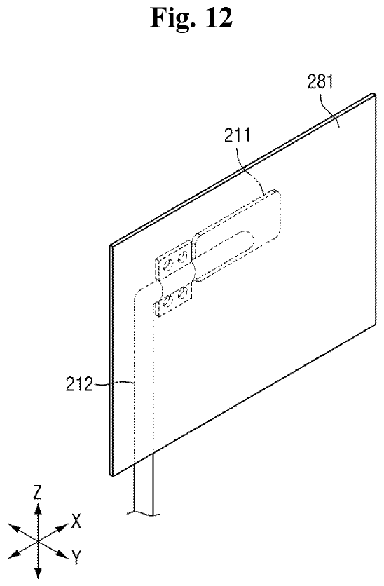

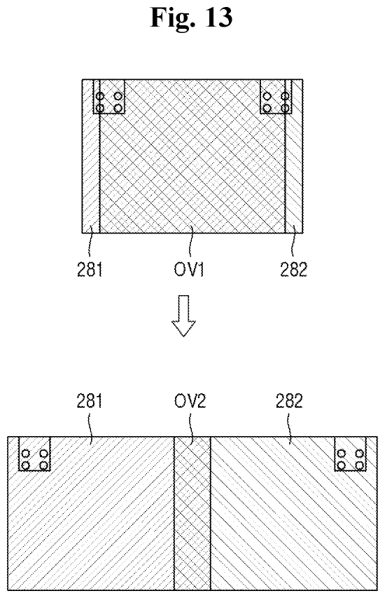

FIGS. 10 and 11 are diagrams for explaining a substrate processing apparatus according to some embodiments of the present invention. FIG. 12 is a diagram for explaining the arrangement of the cover unit of FIG. 10. FIG. 13 is a diagram for explaining the operation of the cover unit of FIG. 10. For convenience of explanation, differences from those described using FIGS. 1 to 9 will be mainly explained.

First, referring to FIG. 10, cover units 281 and 282 may be further installed in the clamping unit 200.

The cover units 281 and 282 are disposed between the vessels 110 and 130 and a heating unit (e.g., a heating unit of the process fluid supply unit 300). The cover units 281 and 282 may block airflow from the space where the heating unit is installed to the space where the vessels 110 and 130 are installed.

The cover units 281 and 282 may include two separate first cover 281 and second cover 282. Unlike what is shown, the cover units 281 and 282 may include only one cover. The first cover 281 may be installed on the first clamp 210, and the second cover 282 may be installed on the second clamp 220.

As shown in FIG. 12, the first cover 281 may be disposed outside the first intake member 211. That is, the first intake member 211 may be disposed closer to the vessels 110 and 130 than the first cover 281. Although not separately shown, the second intake member 221 may be disposed closer to the vessels 110 and 130 than the second cover 282.

By doing this, firstly, the cover units 281, 282 block the airflow generated in the space where the heating unit is installed, and secondarily, the particles coming over the cover units 281, 282 can be removed by the intake members 211, 221. By using the cover units 281 and 282, particle removal efficiency can be improved.

The cover units 281 and 282 are installed in the clamping unit 200. Therefore, as shown in FIG. 11, the cover units 281 and 282 also move according to the movement of the clamping unit 200. There is no need for a separate driving unit to operate the clamping unit 200.

As shown in FIG. 13, the degree to which the first cover 281 and the second cover 282 overlap varies depending on whether the clamping unit 200 is in the locked position or the unlocked position. That is, the area where the first cover 281 and the second cover 282 overlap when the clamping unit 200 is in the locked position (see OV1) is larger than the area where the first cover 281 and the second cover 282 overlap when the clamping unit 200 is in the unlocked position (see OV2).

By forming the first cover 281 and the second cover 282 in this way, the airflow generated in the space where the heating unit is installed without unnecessarily increasing the size of the first cover 281 and the second cover 282 can be blocked efficiently.

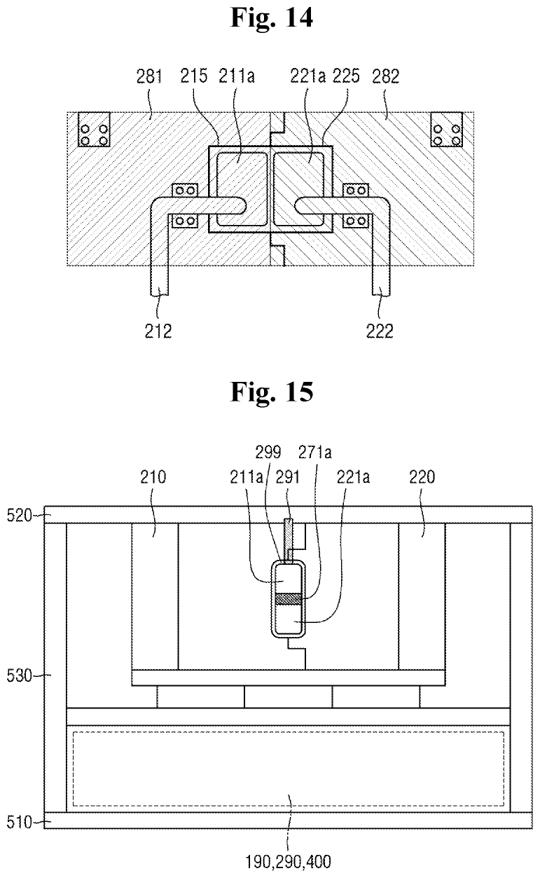

FIG. 14 is a diagram for explaining a substrate processing apparatus according to some embodiments of the present invention. For convenience of explanation, differences from those described using FIGS. 1 to 8 will be mainly explained.

Referring to FIG. 5, the first intake member 211 may be formed across the first groove 215 and the second groove 225. The second intake member 221 may be formed across the first groove 215 and the second groove 225.

On the other hand, referring to FIG. 14, the first intake member 211a is located only within the first groove 215, and the second intake member 221 is located only within the second groove.

FIG. 15 is a diagram for explaining a substrate processing apparatus according to some embodiments of the present invention. For convenience of explanation, differences from those described using FIG. 9 will be mainly explained.

Referring to FIG. 9, the intake members 211 and 221 of the intake unit 250 and the blow member 271 of the cleaning unit 270 are installed in the clamping unit 200. Therefore, as the clamping unit 200 moves, the intake members 211 and 221 and the blow member 271 also move.

On the other hand, referring to FIG. 15, the intake members 211a and 221a and the blow member 271a may be installed on the upper frame 520 through the fixing member 291. Therefore, regardless of the movement of the clamping unit 200, the intake members 211a and 221a and the blow member 271a remain fixed.

The intake members 211a and 221a and the blow member 271a are formed at positions corresponding to the window 299. In the drawing, the blow member 271 is shown as being disposed between the first intake member 211 and the second intake member 221, but the blow member 271 is not limited thereto.

FGIS. 16 and 17 are diagrams for explaining a substrate processing apparatus according to some embodiments of the present invention. For convenience of explanation, differences from those described using FIG. 15 will be mainly explained.

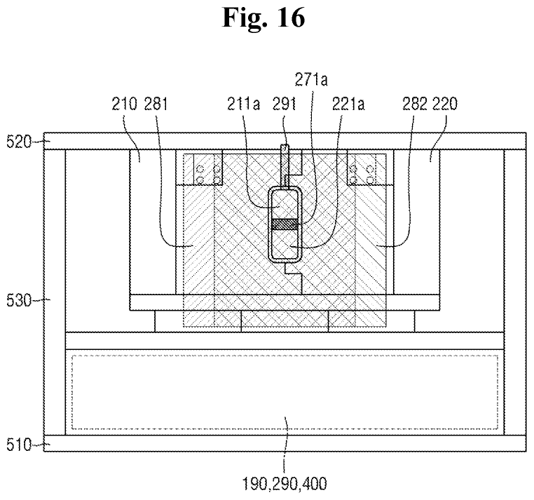

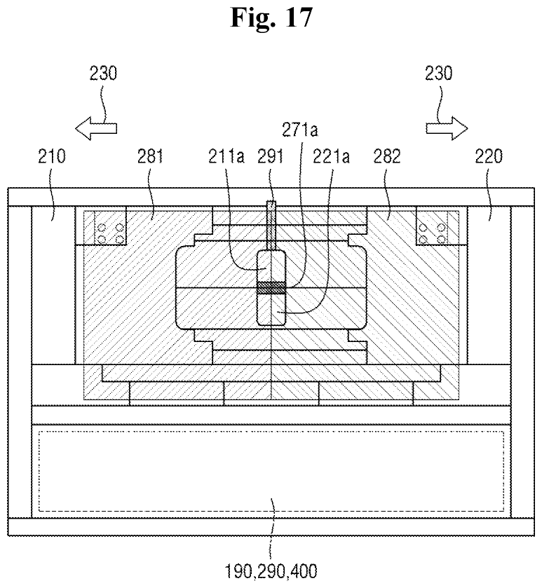

Referring to FIGS. 16 and 17, the intake members 211a and 221a and the blow member 271a may be installed on the upper frame 520 through the fixing member 291. The cover units 281 and 282 are installed in the clamping unit 200. The cover units 281 and 282 are disposed between the vessels 110 and 130 and a heating unit (e.g., a heating unit of the process fluid supply unit 300). As the clamping unit 200 moves, the intake members 211a and 221a and the blowing member 271a do not move, but the cover units 281 and 282 move together.

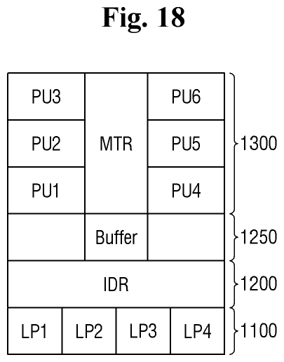

FIG. 18 is a conceptual diagram illustrating a substrate processing apparatus according to some embodiments of the present invention.

Referring to FIG. 18, a substrate processing device apparatus to some embodiments of the present invention comprises a load port 1100, an index module 1200, a buffer module 1250, and a process module 1300. The operations of the load port 1100, index module 1200, buffer module 1250, and process module 1300 may be controlled by a controller (not shown).

The load port 1100 includes a stand on which a container containing a plurality of substrates is placed (see LP1 to LP4). The container may be, for example, a front opening unified pod (FOUP), but is not limited thereto. FIG. 5 illustrates an exemplary case where four stands are installed.

The index module (IDR, 1200) is disposed between the load port 1100 and the buffer module 1250. For example, the index module 1200 includes a rail installed in an index chamber and an index robot that moves along the rail. The index robot includes an arm and a hand, and picks up the substrate located at the load port 1100 and transfers it to the buffer chamber 1250.

The buffer module 1250 temporarily stores the substrate delivered by the index robot of the index module 200. Additionally, a substrate, on which a preset process has been completed, may be temporarily stored in at least one process chamber (PUI to PU6).

The process module 1300 includes a transfer chamber (MTR) and a plurality of process chambers (PUI to PU6).

The transfer chamber (MTR) is arranged to extend long along one direction. Inside the transfer chamber (MTR), a guide rail and a transfer robot that moves along the guide rail are installed.

Centering on the transfer chamber (MTR), process chambers (PUI to PU6) are arranged on both sides. Several process chambers (PU1 to PU3) may be disposed on the left side of the transfer chamber (MTR), and several process chambers (PU4 to PU6) may be disposed on the right side of the transfer chamber (MTR), but are not limited thereto.

For example, the process chamber PUI may be a liquid processing chamber configured to supply a processing liquid to the substrate. The process chamber PU4 may be a drying chamber configured to remove processing liquid remaining on the substrate processed in the liquid processing chamber. As this process chamber PU4, the apparatus described using FIGS. 1 to 17 can be used.

Specifically, in the process chamber PU1, development may be performed by supplying a developer to the substrate. The developer is a developer for negative photosensitive films, and may be, for example, n-butyl acetate (nBA). In the process chamber PU4, the remaining developer can be removed using carbon dioxide in a supercritical state.

As another example, in the process chamber PU1, a rinse treatment may be performed by supplying a rinse solution (e.g., isopropyl alcohol (IPA)) to the substrate. In the process chamber PU4, the remaining rinse solution can be removed using carbon dioxide in a supercritical state.

Here, when the apparatus of FIG. 9 is applied as the process chamber PU4 (i.e., drying chamber), depending on the position of the substrate, the states of the vessels 110 and 130, the clamping unit 200, the intake member 211, 221 and the blow member 271 are summarized in [Table 1] below.

In the following [Table 1], the open state of the clamping unit 200 means an unlocked position, and the closed state means a locked position. The open state of the vessels 110 and 130 means an open position, and the close state means a closed position. The on state of the intake members 211 and 221 means that the intake operation is performed, and the off state means that the intake operation is stopped. The on state of the blow member 271 means that a blow operation is performed, and the off state means that the blow operation is stopped.

TABLE 1

| | | | | | Intake | Blow |
|---|---|---|---|---|---|---|
| | Substrate | | Clamping | | mem- | mem- |
| No. | Position | Process | unit | Vessel | ber | ber |
| 1 | Index Module | Transfer | open | open | on | off |
| | (IDR) | Substrate | | | | |
| 2 | Buffer Module | | open | open | on | off |
| | (Buffer) | | | | | |
| 3 | Transfer Chamber | | open | open | on | off |
| | (MTR) | | | | | |
| 4 | Process Chamber | Rinse | open | open | off | on |
| | (PU1) | | | | | |
| 5 | Transfer Chamber | Transfer | open | open | off | on |
| | (MTR) | Substrate | | | | |
| 6 | Process Chamber | Substate is | open | open | on | off |
| | (PU4) | positioned | | | | |
| 7 | | Wait for | open | close | on | off |
| 8 | | process | close | close | on | off |
| 9 | | Supercritical | close | close | on | off |
| | | fluid | | | | |
| | | process | | | | |
| 10 | | Process is | open | close | on | off |
| | | terminated | | | | |
| 11 | | Pick up | open | open | on | off |
| | | Substrate | | | | |
| 12 | Transfer Chamber | Transfer | open | open | on | off |
| | (MTR) | Substrate | | | | |
| 13 | Buffer Module | | open | open | on | off |
| | (Buffer) | | | | | |
| 14 | Index Module | | open | open | on | off |
| | (IDR) | | | | | |

As summarized in [Table 1], in the process of transferring the substrate (see steps 1 to 3), the intake members 211 and 221 are in the on state, and the blow member 271 is in the off state.

When a rinse operation is performed in the process chamber PUI (see step 4), and in the process of transferring from the process chamber PUI to the process chamber PU4 (see step 5), the intake members 211 and 221 are in the off state, the blow member 271 is in the on state. Before the substrate is introduced into the process chamber PU4, an inert gas is supplied to the open space between the upper vessel 110 and the lower vessel 130 to perform a blow operation.

While a drying operation is performed in the process chamber PU4 (see steps 6 to 11), the intake members 211 and 221 are in the on state and the blow member 271 is in the off state.

Specifically, when positioning the substrate (see step 6), the intake members 211 and 221 is in the on state to begin removing floating particles. Even when the vessels 110 and 130 are closed to wait for the process (see step 7) and the clamping unit 200 is closed (see step 8), the intake members 211 and 221 remain in the on state to remove floating particles. When the supercritical fluid process is terminated (see step 10) and the vessels 110 and 130 are opened to pick up the substrate (see step 11), the intake members 211 and 221 remain in the on state so that particles are prevented from penetrating into the vessel 110, 130.

In the process of transferring the substrate after the drying operation in the process chamber PU4 is completed (see steps 12 to 14), the intake members 211 and 221 are in the on state and the blow member 271 is in the off state.

As described in [Table 1], even before the vessels 110 and 130 are opened (i.e., before they become open positions), the intake members 211 and 221 may remain in the on state.

Alternatively, the intake members 211 and 221 may remain in the on state from the time the vessels 110 and 130 are opened (i.e., from the time they are in the open position).

Alternatively, in order to prevent the spread of particles, unless the situation requires that the intake members 211 and 221 remain in the off state, the intake members 211 and 221 may remain in the on state.

Although embodiments of the present invention have been described with reference to the above and the attached drawings, those skilled in the art will understand that the present invention can be implemented in other specific forms without changing the technical idea or essential features. Therefore, the embodiments described above should be understood in all respects as illustrative and not restrictive.

What is claimed is:

1. An apparatus for processing a substrate comprising:
a vessel including a processing space for processing a substrate, and a first vessel and a second vessel configured to be combined to be open and closed, wherein the first vessel and the second vessel seal the processing space in a closed position, and the first vessel and the second vessel open the processing space in an open position;
a clamping unit configured to clamp the first vessel and the second vessel in the closed position; and
an intake unit configured to intake a particle by including an intake member positioned to correspond to an open space between the first vessel and the second vessel in the open position.

2. The apparatus of claim 1 further comprises,
a heating unit for increasing a temperature of a fluid supplied to the vessel,
wherein the intake member is disposed between the heating unit and the open space.

3. The apparatus of claim 2, wherein the substrate is introduced into the processing space from a first side of the vessel when the first vessel and the second vessel are in the open position,
wherein the heating unit and the intake member are disposed on a second side of the vessel.

4. The apparatus of claim 1, wherein the intake member begins an intake operation before the vessel begins to open.

5. The apparatus of claim 1, wherein the clamping unit is configured to move between a locked position and an unlocked position,
wherein the intake member is installed in the clamping unit, and the intake member moves together according to movement of the clamping unit.

6. The apparatus of claim 5, wherein the clamping unit comprises,
a first clamp configured to clamp one side of the first vessel and the second vessel in the closed position,
a second clamp configured to clamp the other side of the first vessel and the second vessel in the closed position,
wherein the intake member comprises,
a first intake member installed in the first clamp,
a second intake member installed in the second clamp.

7. The apparatus of claim 6, wherein the first clamp includes a first groove, and the second clamp includes a second groove,
wherein, when the clamping unit is in the locked position, the first groove and the second groove are merged to form a window, and at least a portion of the vessel in the closed position is exposed through the window,
wherein the first intake member is installed at a position corresponding to the first groove,
wherein the second intake member is installed at a position corresponding to the second groove.

8. The apparatus of claim 6 further comprises,
a first cover installed on the first clamp and a second cover installed on the second clamp,
wherein an area where the first cover and the second cover overlap when the clamping unit is in the locked position is larger than an area where the first cover and the second cover overlap when the clamping unit is in the unlocked position.

9. The apparatus of claim 6 comprises,
a cleaning unit installed in at least one of the first clamp and the second clamp and for performing a blow operation by supplying an inert gas to the open space before the intake unit performs an intake operation.

10. The apparatus of claim 1 further comprises,
a frame having an accommodation space therein,
wherein the vessel is disposed within the accommodation space,
wherein the intake member is installed on the frame.

11. The apparatus of claim 10, wherein the intake unit comprises a lower frame, an upper frame, and a support frame installed between the lower frame and the upper frame,
wherein the intake member of the intake unit is fixed to the upper frame.

12. The apparatus of claim 11, wherein the first clamp includes a first groove, and the second clamp includes a second groove,
wherein, when the clamping unit is in the locked position, the first groove and the second groove are merged to form a window, and at least a portion of the vessel in the closed position is exposed through the window,
wherein the intake member is installed at a position corresponding to the window.

13. The apparatus of claim 10, wherein the clamping unit comprises,
a first clamp configured to clamp one side of the first vessel and the second vessel in the closed position,
a second clamp configured to clamp the other side of the first vessel and the second vessel in the closed position,
a first cover installed on the first clamp and a second cover installed on the second clamp,
wherein an area where the first cover and the second cover overlap when the clamping unit is in the locked position is larger than an area where the first cover and the second cover overlap when the clamping unit is in the unlocked position.

14. The apparatus of claim 1 further comprises,
a heating unit for increasing a temperature of a fluid supplied to the vessel,
a cover unit installed in the clamping unit and disposed between the vessel and the heating unit for blocking airflow from a space where the heating unit is installed to a space where the vessel is installed.

15. The apparatus of claim 1 further comprises,
a cleaning unit for supplying an inert gas to the open space to perform a blow operation before the intake unit performs an intake operation by including a blow member positioned to correspond to an open space between the first vessel and the second vessel in the open position.

16. An apparatus for processing a substrate comprising:
a liquid processing chamber configured to supply a processing liquid to a substrate;
a drying chamber configured to remove processing liquid remaining on the substrate processed in the liquid processing chamber; and
a transfer chamber for moving the substrate from the liquid processing chamber to the drying chamber,
wherein the drying chamber comprises,
a vessel including a processing space for processing a substrate, and a first vessel and a second vessel configured to be combined to be open and closed, wherein the first vessel and the second vessel seal the processing space in a closed position, and the first vessel and the second vessel open the processing space in an open position,
a clamping unit configured to clamp the first vessel and the second vessel in the closed position,
an intake member configured to intake a particle by including an intake member positioned to correspond to an open space between the first vessel and the second vessel in the open position.

17. The apparatus of claim 16, wherein the processing liquid supplied to the substrate from the liquid processing chamber is isopropyl alcohol (IPA),
wherein carbon dioxide in a supercritical state is supplied from the drying chamber to remove the processing liquid.

18. The apparatus of claim 16 further comprises
a heating unit for increasing a temperature of a fluid supplied to the vessel,
wherein the intake member is disposed between the heating unit and the open space.

19. The apparatus of claim 16 further comprises,
a heating unit for increasing a temperature of a fluid supplied to the vessel,
a cover unit installed in the clamping unit and disposed between the vessel and the heating unit, and for blocking airflow from a space where the heating unit is installed to a space where the vessel is installed.

20. An apparatus for processing a substrate comprising:
a vessel including a processing space for processing a substrate using a fluid, and a first vessel and a second vessel configured to be combined to be open and closed, wherein the first vessel and the second vessel seal the processing space in a closed position. and the first vessel and the second vessel open the processing space in an open position;
a heating unit for increasing a temperature of a fluid supplied to the vessel;
a clamping unit configured to clamp the first vessel and the second vessel in the closed position;
an intake unit configured to intake a particle by including an intake member positioned to correspond to an open space between the first vessel and the second vessel in the open position;
a cleaning unit positioned to correspond to the open space between the first vessel and the second vessel in the open position, and for supplying an inert gas to the open space to perform a blow operation before the intake unit performs an intake operation; and
a cover unit installed in the clamping unit and disposed between the vessel and the heating unit, and for blocking airflow from a space where the heating unit is installed to a space where the vessel is installed,
wherein the clamping unit comprises,
a first clamp for clamping one side of the vessel in the closed position and comprising a first groove;
a second clamp for clamping the other side of the vessel in the closed position and comprising a second groove,
wherein the intake member comprises,
a first intake member installed in the first clamp at a position corresponding to the first groove,
a second intake member installed in the second clamp at a position corresponding to the second groove,
wherein the cover unit comprises,
a first cover installed on the first clamp and disposed outside the first intake member, and a second cover installed on the second clamp and disposed outside the second intake member,
wherein an area where the first cover and the second cover overlap when the clamping unit is in the locked position is larger than an area where the first cover and the second cover overlap when the clamping unit is in the unlocked position.
